(19) United States
(12) Patent Application Publication
(10) Pub. No.: US 2022/0129609 A1
(43) Pub. Date: Apr. 28, 2022

(54) HYBRID METHOD FOR RESERVOIR SIMULATION

(71) Applicant: SAUDI ARABIAN OIL COMPANY, Dhahran (SA)

(72) Inventor: Ali Haydar Dogru, Dhahran (SA)

(73) Assignee: SAUDI ARABIAN OIL COMPANY, Dhahran (SA)

(21) Appl. No.: 17/078,564

(22) Filed: Oct. 23, 2020

(51) Int. Cl. G06F 30/28; G06F 17/18

(52) U.S. Cl. CPC G06F 30/28; G06F 17/18

(57) ABSTRACT

A method for reservoir simulation is disclosed. The method includes selecting a coarse grid size for a plurality of grid blocks in a reservoir model of a reservoir, computing, by a computer processor and based at least on a fractional flow curve of oil and water, a water saturation at a water front within a grid block of the plurality of grid blocks and an average water saturation of the grid block, and computing, by the computer processor and based at least on the water saturation at the water front within the grid block and the average water saturation of the grid block, a water saturation distribution in the reservoir by solving reservoir simulator equations, wherein solving the reservoir simulator equations comprises computing a single water saturation value for each of the plurality of grid blocks based on the coarse grid size.

### BACKGROUND

In the oil and gas industry, reservoir modeling involves the construction of a computer model of a reservoir, for the purposes of improving estimation of reserves and making decisions regarding the development of the field, predicting future production, placing additional wells, and evaluating alternative reservoir management scenarios. A reservoir model represents the physical space of the reservoir by an array of discrete grid blocks, delineated by a grid which may be regular or irregular. The array of grid blocks is usually three-dimensional (3D), although 1D and 2D models are sometimes used. A numerical simulator may be used to perform reservoir simulation that predicts, e.g., the flow of fluids (e.g., oil, water, and gas) through the reservoir based on the reservoir model. During reservoir simulation, attribute values such as porosity, permeability, saturation are associated with each grid block and is implicitly deemed to apply uniformly throughout the volume of the grid block. The grid block is also referred to as a cell or a control volume in the context of reservoir modeling.

### SUMMARY

In general, in one aspect, the invention relates to a method for reservoir simulation. The method includes selecting a coarse grid size for a plurality of grid blocks in a reservoir model of a reservoir, computing, by a computer processor and based at least on a fractional flow curve of oil and water, a water saturation at a water front within a grid block of the plurality of grid blocks and an average water saturation of the grid block, and computing, by the computer processor and based at least on the water saturation at the water front within the grid block and the average water saturation of the grid block, a water saturation distribution in the reservoir by solving reservoir simulator equations, wherein solving the reservoir simulator equations comprises computing a single water saturation value for each of the plurality of grid blocks based on the coarse grid size.

In general, in one aspect, the invention relates to a computer system for performing reservoir simulation. The computer system includes a processor, and a memory coupled to the processor and storing instruction. The instructions, when executed by the processor, include functionality for selecting a coarse grid size for a plurality of grid blocks in a reservoir model of a reservoir, computing, based at least on a fractional flow curve of oil and water, a water saturation at a water front within a grid block of the plurality of grid blocks and an average water saturation of the grid block, and computing, based at least on the water saturation at the water front within the grid block and the average water saturation of the grid block, a water saturation distribution in the reservoir by solving reservoir simulator equations, wherein solving the reservoir simulator equations comprises computing a single water saturation value for each of the plurality of grid blocks based on the coarse grid size.

Other aspects and advantages will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1 and 2 show systems in accordance with one or more embodiments.

FIG. 3 shows a flowchart in accordance with one or more embodiments.

FIGS. 4.1-4.16 show an example in accordance with one or more embodiments.

FIGS. 5A and 5B show a computing system in accordance with one or more embodiments.

### DETAILED DESCRIPTION

Specific embodiments of the disclosure will now be described in detail with reference to the accompanying figures. Like elements in the various figures are denoted by like reference numerals for consistency.

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Embodiments of the invention provide a method, a system, and a non-transitory computer readable medium for performing reservoir simulation based on a coarse grid size while mitigating a numerical dispersion artifact caused by the coarse grid size. In one or more embodiments of the invention, the reservoir simulation is based on a hybrid method that provides an analytically generated critical water saturation to a numerical reservoir simulator for determining water breakthrough between adjacent upstream grid cell and downstream grid cell. In one or more embodiments of the invention, the critical water saturation is generated from an empirical saturation equation formulated with an empirical parameter to describe a water saturation distribution within the grid cell behind a water front. Using the analytically generated critical water saturation as the criteria for determining water breakthrough reduces the numerical dispersion caused by the coarse grid size in the numerical reservoir simulator. In one or more embodiments of the invention, relative permeability curves are modified based at least on the critical water saturation. The modified relative permeability curves are used by the numerical reservoir simulator to preserve a pressure field with respect to simulation result based on a fine grid size.

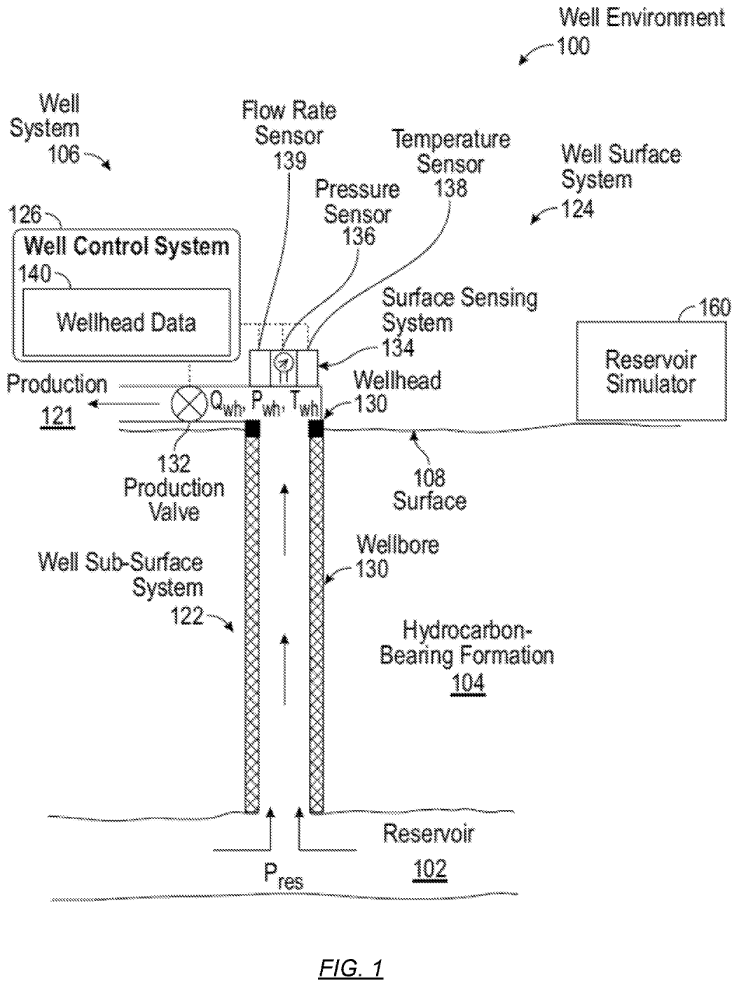

FIG. 1 shows a schematic diagram in accordance with one or more embodiments. More specifically, FIG. 1 illustrates a well environment (100) that includes a hydrocarbon reservoir (“reservoir”) (102) located in a subsurface hydrocarbon-bearing formation (“formation”) (104) and a well system (106). The hydrocarbon-bearing formation (104) may include a porous or fractured rock formation that resides underground, beneath the earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

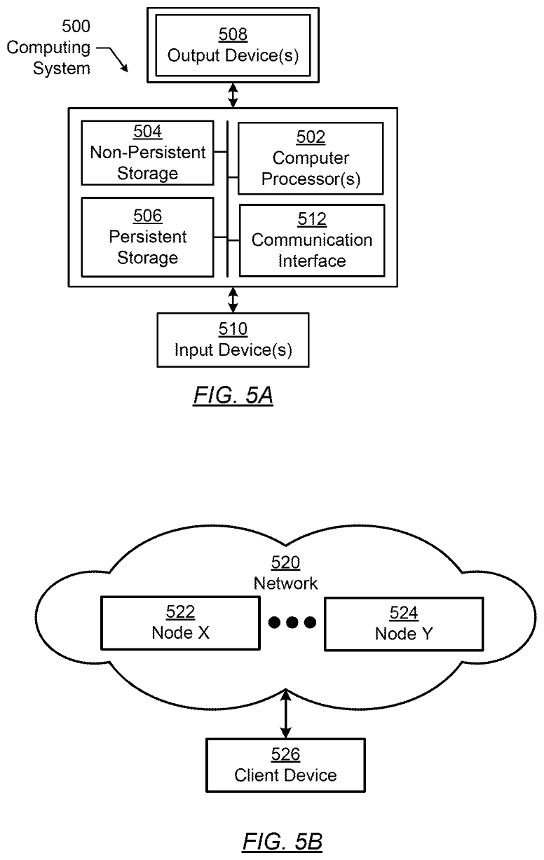

In some embodiments, the well system (106) includes a wellbore (120), a well sub-surface system (122), a well surface system (124), and a well control system (“control system”) (126). The control system (126) may control various operations of the well system (106), such as well production operations, well completion operations, well maintenance operations, and reservoir monitoring, assessment and development operations. In some embodiments, the control system (126) includes a computer system that is the same as or similar to that of computer system (500) described below in FIGS. 5A and 5B and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In some embodiments, during operation of the well system (106), the control system (126) collects and records wellhead data (140) for the well system (106). The wellhead data (140) may include, for example, a record of measurements of wellhead pressure (P_{wh}) (e.g., including flowing wellhead pressure), wellhead temperature (T_{wh}) (e.g., including flowing wellhead temperature), wellhead production rate (Q_{wh}) over some or all of the life of the well (106), and water cut data. In some embodiments, the measurements are recorded in real-time, and are available for review or use within seconds, minutes or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well (106) to assess a relatively current state of the well system (106), and make real-time decisions regarding development of the well system (106) and the reservoir (102), such as on-demand adjustments in regulation of production flow from the well.

In some embodiments, the well sub-surface system (122) includes casing installed in the wellbore (120). For example, the wellbore (120) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In some embodiments, the casing includes an annular casing that lines the wall of the wellbore (120) to define a central passage that provides a conduit for the transport of tools and substances through the wellbore (120). For example, the central passage may provide a conduit for lowering logging tools into the wellbore (12), a conduit for the flow of production (121) (e.g., oil and gas) from the reservoir (102) to the surface (108), or a conduit for the flow of injection substances (e.g., water) from the surface (108) into the hydrocarbon-bearing formation (104). In some embodiments, the well sub-surface system (122) includes production tubing installed in the wellbore (120). The production tubing may provide a conduit for the transport of tools and substances through the wellbore (120). The production tubing may, for example, be disposed inside casing. In such an embodiment, the production tubing may provide a conduit for some or all of the production (121) (e.g., oil and gas) passing through the wellbore (120) and the casing.

In some embodiments, the well surface system (124) includes a wellhead (13). The wellhead (130) may include a rigid structure installed at the “up-hole” end of the wellbore (120), at or near where the wellbore (120) terminates at the Earth's surface (108). The wellhead (130) may include structures for supporting (or “hanging”) casing and production tubing extending into the wellbore (120). Production (12) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (12). For example, the well surface system (124) may include one or more production valves (132) that are operable to control the flow of production (134). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

In some embodiments, the wellhead (130) includes a choke assembly. For example, the choke assembly may include hardware with functionality for opening and closing the fluid flow through pipes in the well system (106). Likewise, the choke assembly may include a pipe manifold that may lower the pressure of fluid traversing the wellhead. As such, the choke assembly may include set of high pressure valves and at least two chokes. These chokes may be fixed or adjustable or a mix of both. Redundancy may be provided so that if one choke has to be taken out of service, the flow can be directed through another choke. In some embodiments, pressure valves and chokes are communicatively coupled to the well control system (126). Accordingly, a well control system (126) may obtain wellhead data regarding the choke assembly as well as transmit one or more commands to components within the choke assembly in order to adjust one or more choke assembly parameters.

Keeping with FIG. 1, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In some embodiments, the surface sensing system (134) includes a surface pressure sensor (136) operable to sense the pressure of production (151) flowing through the well surface system (124), after it exits the wellbore (120). The surface pressure sensor (136) may include, for example, a wellhead pressure sensor that senses a pressure of production (121) flowing through or otherwise located in the wellhead (130). In some embodiments, the surface sensing system (134) includes a surface temperature sensor (138) operable to sense the temperature of production (151) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (T_{wh}). In some embodiments, the surface sensing system (134) includes a flow rate sensor (139) operable to sense the flow rate of production (151) flowing through the well surface system (124), after it exits the wellbore (120). The flow rate sensor (139) may include hardware that senses a flow rate of production (121) (Q_{wh}) passing through the wellhead (130).

In some embodiments, the well system (106) includes a reservoir simulator (160). For example, the reservoir simulator (160) may include hardware and/or software with functionality for generating one or more reservoir models regarding the hydrocarbon-bearing formation (104) and/or performing one or more reservoir simulations. For example, the reservoir simulator (160) may store well logs and data regarding core samples for performing simulations. A reservoir simulator may further analyze the well log data, the core sample data, seismic data, and/or other types of data to generate and/or update the one or more reservoir models. While the reservoir simulator (160) is shown at a well site, embodiments are contemplated where reservoir simulators are located away from well sites. In some embodiments, the reservoir simulator (160) may include a computer system that is similar to the computer system (500) described below with regard to FIGS. 5A and 5B and the accompanying description.

A reservoir simulator may include functionality for solving well equations and reservoir equations separately, e.g., using Additive Schwartz methods. When the number of wells in a simulation is relatively small, computation time spent solving well equations may be a small fraction of the total computation time. However, in massive full-field simulations, where hundreds or thousands of wells are being simulated, the total computation time for solving well equations may increase considerably. This may be particularly true when a multi-segment well model is used as the number of unknown well parameters to be solved may be much larger than a conventional well model. As such, reservoir simulators may assign wells to computer processes in parallel computing tasks statically and/or dynamically. For example, at the beginning of a reservoir simulation, a well may be assigned to a single computer process that performs the computations necessary for this well. In some embodiments, placement of a well within a computer process may be independent of grid partitioning, e.g., whether the well is surrounded by fine-grid grid blocks or coarsened grid blocks. During a simulation, a computer process may access both grid data for a reservoir model and well data. As such, well assignment may affect such parallel communication patterns and thereby may influence reservoir simulation performance.

In some embodiments, well assignment for parallel computer processes may include the case where a number of wells being simulated is greater than the number of computer processes involved in a reservoir simulation. Thus, multiple wells may be assigned to one computer process operating within a parallel processing stage. As wells may not need to be solved at all times during a reservoir simulation, e.g., only when the wells are producing or injecting, a situation may occur where one computer process is solving equations for multiple wells while a production well assigned to another computer process is inactive causing the computer process to be idle (i.e., waiting for the other computer processes to finish in the parallel processing stage).

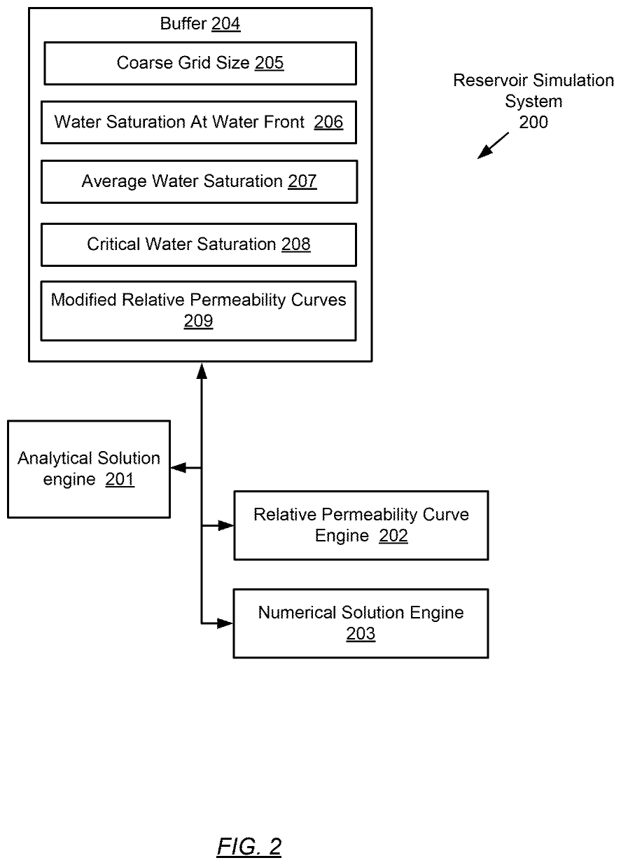

Turning to FIG. 2, FIG. 2 shows a schematic diagram in accordance with one or more embodiments. In one or more embodiments, one or more of the modules and/or elements shown in FIG. 2 may be omitted, repeated, and/or substituted. Accordingly, embodiments of the invention should not be considered limited to the specific arrangements of modules and/or elements shown in FIG. 2.

FIG. 2 illustrates a reservoir simulation system (200) that has multiple components, including, for example, a buffer (204), an analytical solution engine (201), a relative permeability curve engine (202), and a numerical solution engine (203). Each of these components (201, 202, 203, 204) may be located on the same computing device (e.g., personal computer (PC), laptop, tablet PC, smart phone, multifunction printer, kiosk, server, etc.) or on different computing devices that are connected via a network, such as a wide area network or a portion of Internet of any size having wired and/or wireless segments. Each of these components is discussed below. In one or more embodiments of the invention, the reservoir simulation system (200) is at least part of the reservoir simulator (106) depicted in FIG. 1 above.

In one or more embodiments of the invention, the buffer (204) may be implemented in hardware (i.e., circuitry), software, or any combination thereof. The buffer (204) is configured to store data generated and/or used by the reservoir simulation system (200). The data stored in the buffer (204) includes the coarse grid size (205), the water saturation at water front (206), the average water saturation (207), the critical water saturation (208), and the modified relative permeability curves (209).

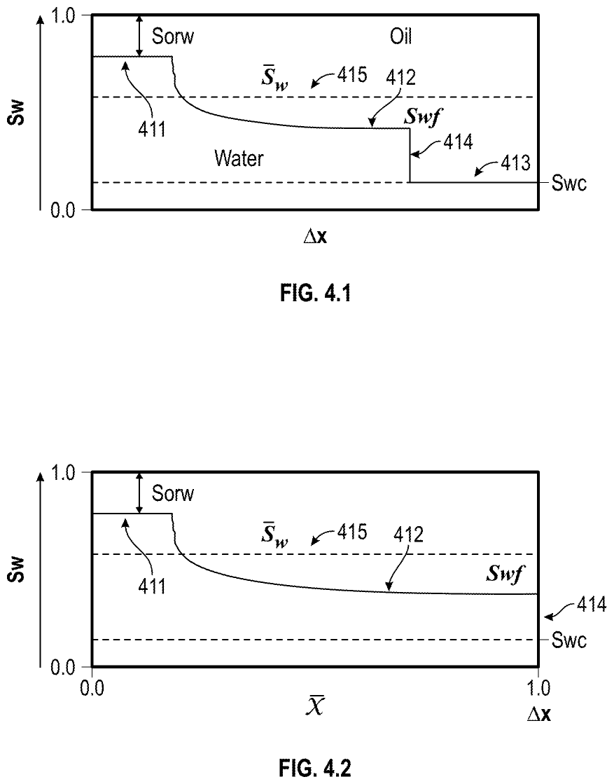

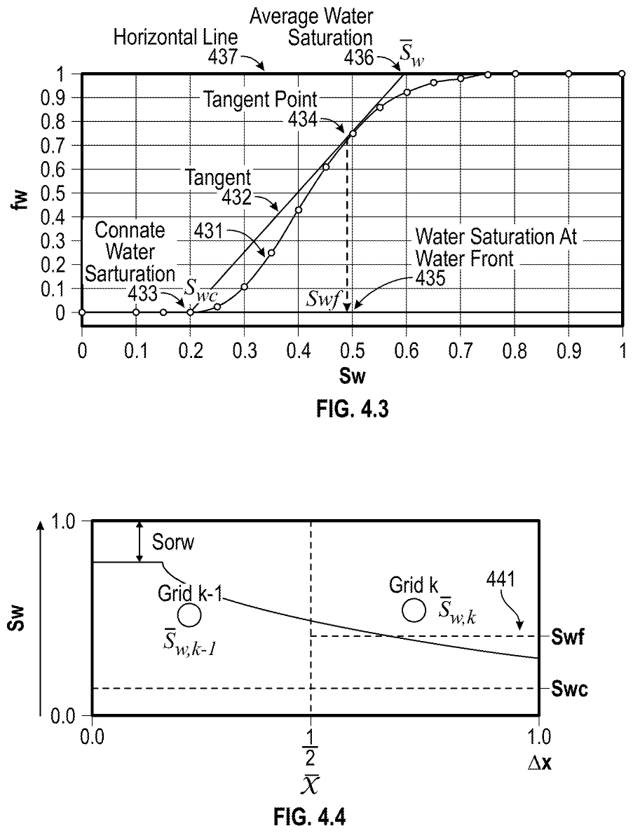

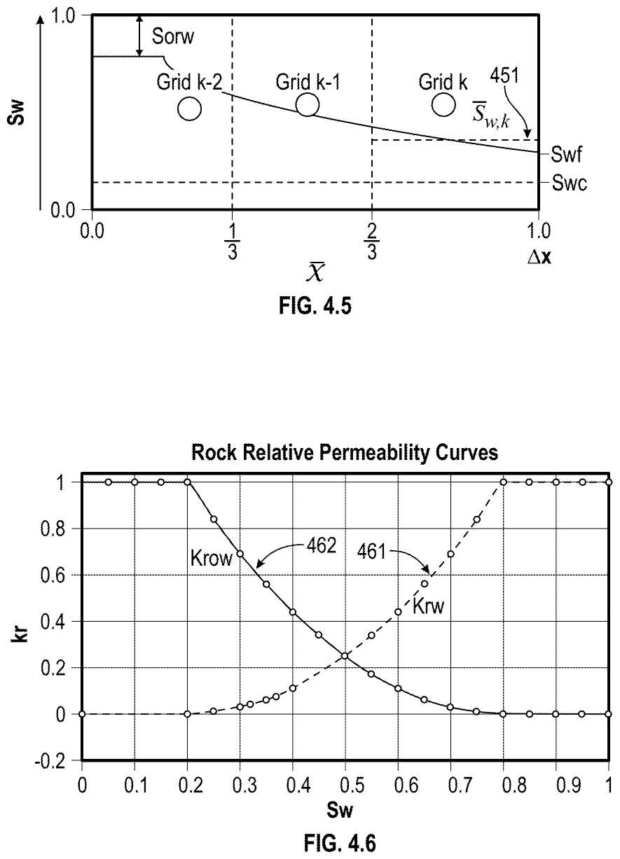

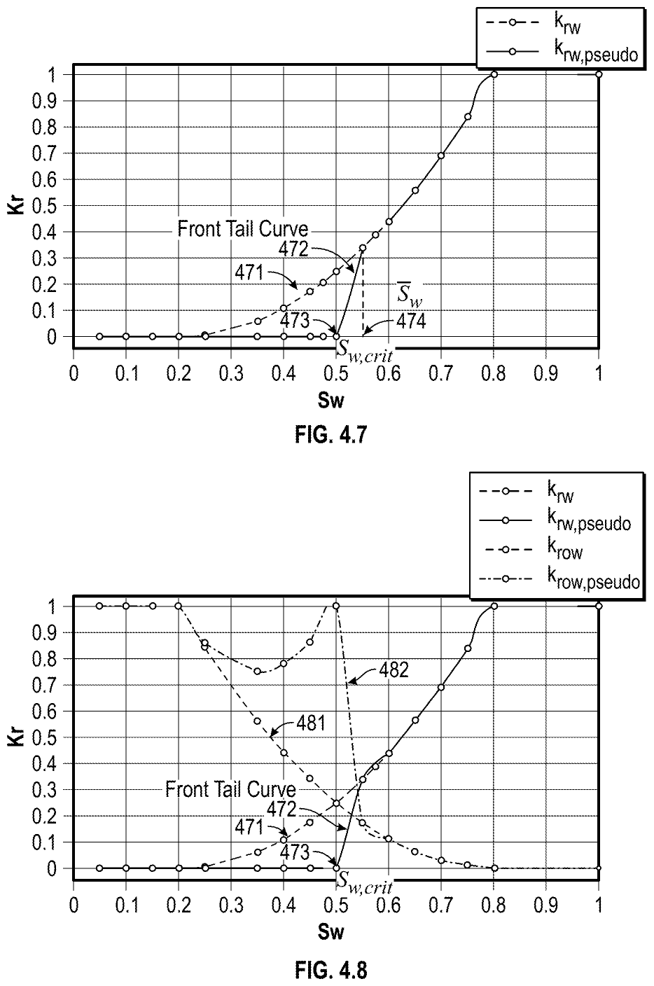

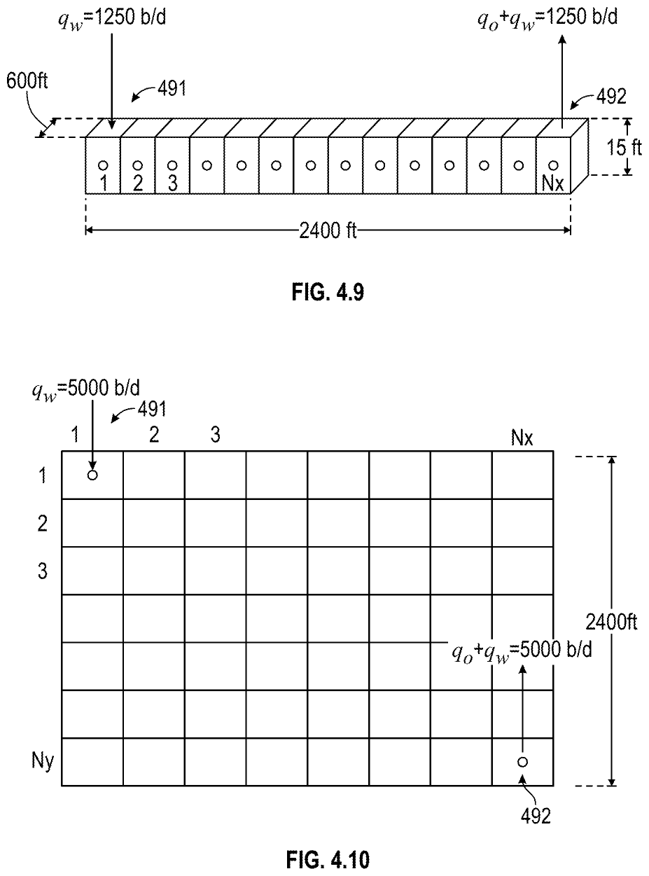

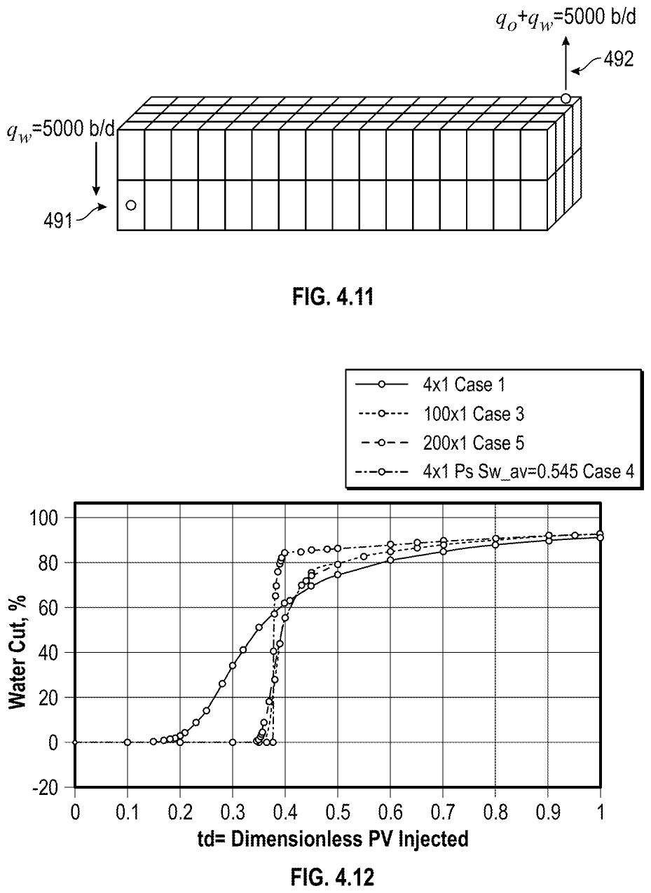

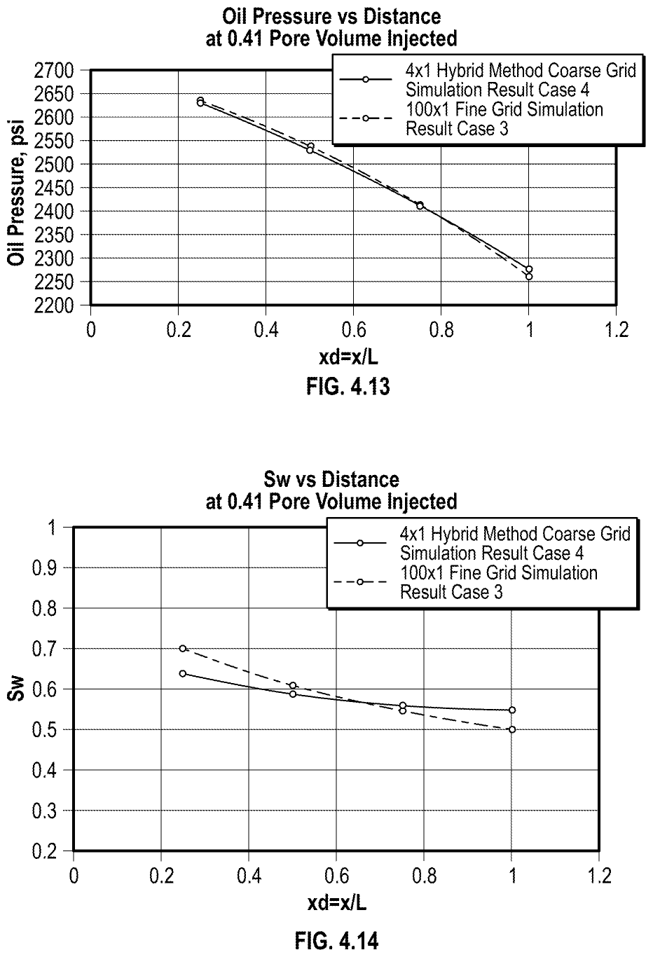

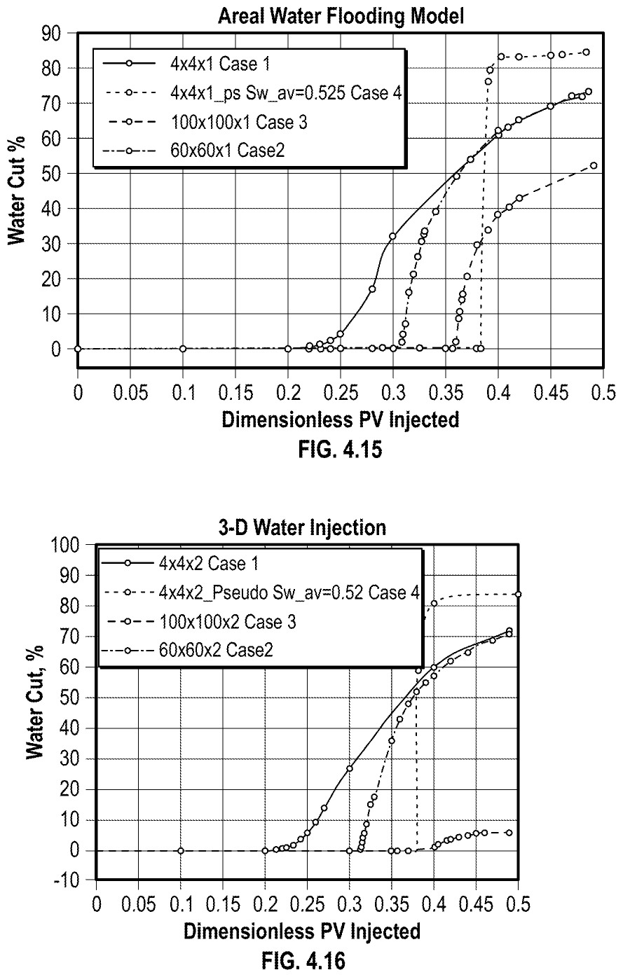

The coarse grid size (205) is a dimension of the grid block that exceeds a predetermined threshold, such as one hundred meters or larger. The predetermined threshold is defined such that any grid size less than the predetermined threshold is sufficiently small where further reduction in the grid size does not result in any significant change (e.g., less than 5%) in the simulation result. Examples of the grid size (205) are described in reference to FIGS. 4.9-4.11 below.

The water saturation at water front (206) is the water saturation at an advancing and leading boundary of injected water movement in the reservoir or a grid cell of the reservoir model. An example of the water saturation at water front (206) is described in reference to FIGS. 4.1-4.2 and 4.4-4.5 below.

The average water (207) is a numerical average of the water saturation distribution behind the water front in a grid cell. An example of the average water saturation (207) is described in reference to FIGS. 4.1-4.2 and 4.4-4.5 below.

The critical water saturation (208) is an analytically generated threshold that is used as simulation criteria for determining water breakthrough between adjacent upstream and downstream grid blocks.

The modified relative permeability curves (209) are oil and water permeability curves that are modified based at least on the critical water saturation and are used by the numerical reservoir simulator to preserve pressure field solutions based on coarse grid size with respect to more accurate simulation solution based on a fine grid size.

In one or more embodiments of the invention, each of the analytical solution engine (201), relative permeability curve engine (202), and numerical solution engine (203) may be implemented in hardware (i.e., circuitry), software, firmware, or any combination thereof.

In one or more embodiments of the invention, the analytical solution engine (201) is configured to generate the water saturation at water front (206), the average water saturation (207), and the critical water saturation (208). In one or more embodiments, the analytical solution engine (201) generates the water saturation at water front (206) and the average water saturation (207) according to a Welge method, i.e., by applying the Welge equation to the fractional flow curve of the reservoir rock as porous media. In one or more embodiments, the analytical solution engine (201) generates the critical water saturation (208) by formulating and solving an empirical saturation equation that describes the water saturation distribution within the grid cell behind a water front.

In one or more embodiments disclosed herein, the relative permeability curve engine (202) is configured to modify the oil and water relative permeability curves so as to preserve pressure field solutions of the coarse grid reservoir simulation with respect to the more accurate solution of a fine grid reservoir simulation. In one or more embodiments, the relative permeability curve engine (202) modifies the oil and water relative permeability curves based at least on the critical water saturation.

In one or more embodiments disclosed herein, the numerical solution engine (203) is configured to perform reservoir simulation using a conventional numerical reservoir simulator. In particular, the conventional numerical reservoir simulator generates a simulation results by computing a single saturation value for each grid block instead of considering the saturation distribution within any grid block. Further, in the conventional reservoir simulation, the numerical reservoir simulator determines the water breakthrough between upstream and downstream grid cells by comparing the simulator computed water saturation and a connate water saturation, which is the inherent water saturation existing on the reservoir rock. In the hybrid method of reservoir simulation, the numerical reservoir simulator determines the water breakthrough between upstream and downstream grid cells by comparing the simulator computed water saturation and the analytically generated critical water saturation.

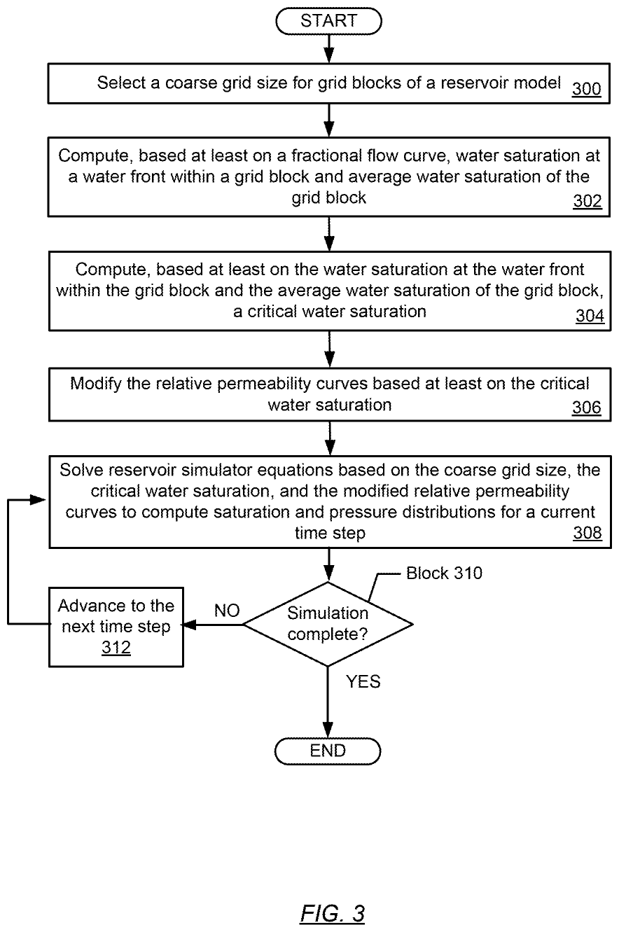

In one or more embodiments, the reservoir simulation system (200) performs the functionalities described above using the method described in reference to FIG. 3 below. Although the reservoir simulation system (200) is shown as having three engines (201, 202, 203), in other embodiments of the invention, the reservoir simulation system (200) may have more or fewer engines and/or more or fewer other components. Further, the functionality of each component described above may be split across components. Further still, each component (201, 202, 203) may be utilized multiple times to carry out an iterative operation.

FIG. 3 shows a flowchart in accordance with one or more embodiments. Specifically, FIG. 3 describes a hybrid method of reservoir simulation. One or more blocks in FIG. 3 may be performed using one or more components as described in FIGS. 1 and 2. While the various blocks in FIG. 3 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

Initially in Block 300, a coarse grid size (e.g., one hundred meters or larger) is selected for grid blocks in a reservoir model of a reservoir. In comparison, a fine grid size is a sufficiently small grid size such that further reduction in the grid size does not result in any significant change (e.g., less than 5%) in the simulation result. Generally, fine grid size is less than 50-meter on each side.

In Block 302, a water saturation at a water front within a grid block and an average water saturation of the grid block are computed based at least on a fractional flow curve of oil and water. In one or more embodiments, the water saturation at the water front within the grid block and the average water saturation of the grid block are computed by solving a Welge equation of the fractional flow curve based on a local boundary condition. An example of the Welge equation is described as Eq. (13) below. An example of solving a Welge equation of the fractional flow curve is described in reference to FIG. 4.3 below.

In Block 304, a critical saturation is computed based at least on the the water saturation at the water front within the grid block and the average water saturation of the grid block. In one or more embodiments, an empirical saturation equation is formulated to describe the water saturation distribution in a partially water swept rock region behind the water front in the grid block. The empirical saturation equation includes at least one empirical parameter that is determined by applying the water saturation at the water front within the grid block and the average water saturation of the grid block to the empirical saturation equation. With the known empirical parameter, the empirical saturation equation is integrated, over the grid block based on the water front reaching a downstream boundary of the grid block, to compute a critical water saturation. An example of the empirical saturation equation and computing the critical water saturation is described in reference to FIGS. 4.4-4.5 and Eq. (14) through Eq. (19) below.

In Block 306, oil and water relative permeability curves of the reservoir model are modified within a saturation range. The saturation range is determined based at least on the critical saturation. In one or more embodiments, the modified oil and water relative permeability curves are used by the reservoir simulator for solving the reservoir simulator equations. An example of the reservoir simulator equations is described as Eq. (1) through Eq. (12) below. In one or more embodiments, modifying the oil and water relative permeability curves includes adding a front tail to the oil and water relative permeability curves within the saturation range. An example of adding the front tail is described in reference to FIGS. 4.7-4.8 below. In one or more embodiments, modifying the oil and water relative permeability curves preserves a pressure solution with respect to a fine grid reservoir simulation solution. An example of preserving the pressure solution with respect to a fine grid reservoir simulation solution is described in reference to FIG. 4.13 below.

In Block 308, a set of reservoir simulator equations are solved to compute a water saturation distribution in the reservoir for a current time step. In one or more embodiments, solving the reservoir simulator equations includes computing a single water saturation value for each of the grid blocks of the reservoir model based on the coarse grid size. In one or more embodiments, solving the reservoir simulator equations includes determining water starting flowing into a neighboring downstream grid block when a simulator computed water saturation reaches the critical water saturation. An example set of the reservoir equations is described as Eq. (1) through Eq. (12) below.

In Block 310, a determination is made as to whether the simulation is complete. If the determination is positive, i.e., the simulation is complete, the method ends. If the determination is negative, i.e., the simulation is not complete, the time step is incremented (Block 312) before the method returns to the Block 308 to compute the water saturation distribution in the reservoir for a subsequent time step.

In one or more embodiments, water movement across the reservoir is simulated by computing the water saturation distribution for each of a sequence of time steps of the reservoir simulation. In one or more embodiments, a field operation (e.g., a field development operation, a drilling operation, a injection operation, a production operation, etc.) is performed based at least on the water saturation distribution and the water movement in the reservoir.

FIGS. 4.1-4.14 provide examples of the hybrid method of reservoir simulation. The hybrid method combines a numerical solution with a local analytical solution to improve the accuracy of a numerical reservoir simulator. The example shown in FIGS. 4.1-4.14 may be, for example, based on one or more components depicted in FIGS. 1-2 above and the method flowchart depicted in FIG. 3 above. In one or more embodiments, one or more of the modules and/or elements shown in FIGS. 4.1-4.14 may be omitted, repeated, and/or substituted. Accordingly, embodiments of the invention should not be considered limited to the specific arrangements of modules and/or elements shown in FIGS. 4.1-4.14.

In reservoir simulation, full field models are often used to simulate long production history of hydrocarbon fields with hundreds of wells. Generally, coarse grid sizes (e.g., one hundred meters or larger) are used for large hydrocarbon fields. Using coarse grids (i.e., grids based on coarse grid sizes) causes the reservoir simulator to predict or otherwise indicate a fluid (e.g., water and/or gas) breakthrough at a grid block (e.g., at the wells) that is earlier than the true result. This phenomenon is known as the numerical dispersion, which is due to coarse grid sizes used by the reservoir simulator to perform the simulation.

Instead of using coarse grid sizes, finer grid sizes may be used to reduce numerical dispersion. Fine grid models are defined as having a sufficiently small grid size such that further reduction in the grid size does not result in any significant change (e.g., <5%) in the simulation result. As described above, fine grid models may use 50-meter grid block sizes or smaller. However, fine grid models require excessive and often impractical computation time. On the other hand, coarse grid models allow faster simulation to provide more opportunities to simulate a large number of alternative operating scenarios. The hybrid method described below combines the coarse grid numerical solution of the reservoir simulator with the analytical solution at the grid block level. The combination improves the accuracy of predicted fluid breakthrough times at wells to be close to the fine grid models with significantly reduced computation time.

In an oil reservoir, the water cut is the ratio of water flow compared to the total liquid flow. Water saturation (denoted as S_{w}) is the ratio of water volume to pore volume. Oil saturation is 1 (one) minus the water saturation. Permeability is a measure of ability for the rocks to transmit fluids, such as water or oil. Relative permeability is the ratio of effective permeability of a particular fluid at a particular saturation to absolute permeability of that fluid at total saturation. The relative permeability curve is the plot of relative permeability versus water saturation.

In fluid dynamics, the Buckley-Leverett (BL) equation is a conservation equation to model two-phase fluid flow in porous media. The BL equation may be solved to generate an analytical solution (referred to as the BL analytical solution) that estimates the rate at which an injected water front moves through a porous medium, such as an oil reservoir. The Buckley-Leverett equation is based on fractional flow theory with the assumptions that fluid flow is linear and horizontal, oil and water are both incompressible and immiscible, and gravity and capillary pressure effects are negligible. In the fractional flow theory, the immiscible fluid displacement process is described by the fractional flow curve, which is the plot of water cut (denoted as f_{w}) in the two-phase fluid flow versus water saturation (denoted as S_{w}).

The hybrid method is demonstrated below to model a water injection problem into an oil reservoir using a conventional reservoir simulator with a coarse grid size, as well as a critical water saturation and modified relative permeability curves from the BL anlytical solution. The analytical solution at the grid block level of the hybrid method is based on the BL analytical solution within a small number (e.g., 2 or 3) of consecutive grid blocks. The hybrid method is based on the assumption that water will not flow into a downstream grid block until the water saturation at the water front (denoted as S_{wf}) reaches the interface between the upstream and downstream grid blocks. In other words, the hybrid method considers the saturation as a distribution across the grid block instead of as a single value for the grid block. In particular, S_{wf} is calculated based on the BL analytical solution as moving from the upstream boundary to the downstream boundary of the grid block. As the water front S_{wf} reaches the downstream grid block boundary, water saturation behind the water front increases in the upstream direction. The water saturation distribution in the grid block is used to compute the average saturation of the grid block, referred to as the BL analytical solution based average saturation. In contrast, the reservoir simulator computes only a single value of the saturation for each grid block without considering the saturation distribution within the grid block. The single saturation value is then applied to the relative permeability curves to compute the water movement into the next grid block.

Generally, the BL analytical solution based average saturation is different from and more accurate than the simulator computed average saturation. Specifically, the simulator computed average saturation includes numerical dispersion while the BL analytical solution based average does not. Accordingly, the BL analytical solution generates more accurate result of computed water movement into the next grid block than the reservoir simulator. The hybrid method applies the BL analytical solution to correct the simulator computed average saturation and the oil-water relative permeability curves. This correction is performed once without being performed dynamically at every time step during the reservoir simulation. The corrected oil-water relative permeability curves are then used by the reservoir simulator to compute fluid breakthrough time at the wells.

In the hybrid method, an empirical saturation equation is used to describe the saturation distribution within a grid block and behind the water front. Initially, parameters of the empirical saturation equation are determined by the local boundary conditions and the Welge method. The Welge method is a method for predicting fluid transport in porous media as described in reference to FIG. 4.3 and Eq. (13) below.

For the next step in the hybrid method, the average water saturation for the upstream grid blocks are calculated as critical water saturation (CWS, also denoted as S_{w,crit}) by integrating the empirical saturation equation within the grid block and behind the water front. Connate water saturation (denoted as S_{wc}) is the amount of the water adsorbed on the surface of the rock grains or on the walls of the porous rock pores divided by the pore volume. In comparison, CWS is greater than the connate water saturation (S_{wc}) in water relative permeability curves. The hybrid method assumes that no water will flow into the downstream grid block if the simulator computed grid block saturation is less than CWS. Throughout this disclosure, CWS and S_{w,crit} are used interchangeably. This is in contrast to the conventional reservoir simulator that assumes no water will flow into the downstream grid block if the simulator computed grid block saturation is less than the connate water saturation (S_{wc}).

In conventional approaches, e.g., as described in a Society of Petroleum Engineers paper SPE-187991-MS, the water relative permeability curve is modified to start from S_{wc} without modifying the oil relative permeability curve. In contrast, the hybrid method modifies the water relative permeability curve to start from the CWS to correct coarse grid fluid saturations. In addition, the oil relative permeability curve is also modified by the hybrid method to preserve the pressure field of the fine grid simulation. Specifically, the coarse grid pressure field is corrected to be similar to fine grid pressures. Based on the shape of the water relative permeability curve, the resulting oil relative permeability curve may be non-monotonically decreasing and may contain a local maximum. Resulting water and oil relative permeability curves resemble pseudo relative permeability functions, e.g., as described in a Society of Petroleum Engineers paper SPE-54589-MS. The oil and water relative permeability curves are modified only once at the input level of the reservoir simulator.

In the hybrid method, the reservoir simulator uses partial differential equations with constraints to describe the fluid flow in the porous media. For example, Eq. (1) below describes the oil flow and Eq. (2) described the water flow.

$$\begin{matrix}\frac{\partial }{\partial x} ( {k}_{x} \frac{{k}_{ro}}{{μ}_{o}} {ρ}_{o} \frac{\partial {Φ}_{o}}{\partial x} ) + \frac{\partial }{\partial y} ( {k}_{y} \frac{{k}_{ro}}{{μ}_{o}} {ρ}_{o} \frac{\partial {Φ}_{o}}{\partial y} ) + \frac{\partial }{\partial z} ( {k}_{z} \frac{{k}_{ro}}{{μ}_{o}} {ρ}_{o} \frac{\partial {Φ}_{o}}{\partial z} ) - {q}_{o} {ρ}_{o} = \frac{\partial }{\partial t} ( {∅ρ}_{o} {S}_{o} ) & ( 1 ) \\ \frac{\partial }{\partial x} ( {k}_{x} \frac{{k}_{rw}}{{μ}_{w}} {ρ}_{w} \frac{\partial {Φ}_{w}}{\partial x} ) + \frac{\partial }{\partial y} ( {k}_{y} \frac{{k}_{rw}}{{μ}_{w}} {ρ}_{w} \frac{\partial {Φ}_{w}}{\partial y} ) + \frac{\partial }{\partial z} ( {k}_{z} \frac{{k}_{rw}}{{μ}_{w}} {ρ}_{w} \frac{\partial {Φ}_{w}}{\partial z} ) - {q}_{w} {ρ}_{w} = \frac{\partial }{\partial t} ( {∅ρ}_{w} {S}_{w} ) & ( 2 )\end{matrix}$$

In Eq. (1) and Eq. (2), kₓ, k_{y} and k_{z} are the absolute rock permeability in x, y and z dimensions, Φₒ and Φ_{w} are oil and water potentials, μₒ and μ_{w} are oil and water viscosities, ρₒ and ρₒ are oil and water densities, ∅ is the rock porosity, Sₒ and S_{w} are oil and water saturation in the rock, k_{rw} (S_{w}) and kᵣₒ(S_{w}) are water and oil relative permeabilities, and qₒ and q_{w} are well production/injection rates.

Eq. (3) through Eq. (9) describe auxiliary relationships as constraints for Eq. (1) and Eq. (2).

$$\begin{matrix}{S}_{o} + {S}_{w} = 1 & ( 3 ) \\ {Φ}_{o} = {p}_{o} - \frac{g}{{g}_{c}} {ρ}_{o} ( z - {z}_{ref} ) & ( 4 ) \\ {Φ}_{w} = {p}_{w} - \frac{g}{{g}_{c}} {ρ}_{w} ( z - {z}_{ref} ) & ( 5 ) \\ {p}_{cow} = {p}_{o} - {p}_{w} = f ( {s}_{w} ) & ( 6 ) \\ {c}_{r} = \frac{1}{ϕ} {( \frac{\partial ∅}{\partial p} )}_{T} & ( 7 ) \\ {c}_{o} = \frac{1}{{ρ}_{o}} {( \frac{\partial {ρ}_{o}}{\partial p} )}_{T} & ( 8 ) \\ {c}_{w} = \frac{1}{{ρ}_{w}} {( \frac{\partial {ρ}_{w}}{\partial p} )}_{T} & ( 9 )\end{matrix}$$

In Eq. (4) through Eq. (9), pₒ is the oil pressure, p_{w} is the water pressure,

$$\frac{g}{{g}_{c}}$$

is the gravitational constant converted to practical units, z is the depth of the rock formation and z_{ref} is the reference depth, p_{cow} is the oil/water capillary pressure, ƒ(s_{w}) is the fractional flow curve, cᵣ, cₒ, c_{w} are pore compressibility of the rock, oil and water, and T as a subscript indicates that relation is evaluated at constant temperature.

For a multi-dimensional flow such as three dimensions, Eq. (1) and Eq. (2) may be generalized to Eq. (10) below.

$$∇ \cdot K \frac{{k}_{rj}}{{μ}_{j}} ∇ {Φ}_{j} - δ ( x , y , x , t ) {q}_{j} {ρ}_{j} = \frac{\partial }{\partial t} ( {∅ρ}_{j} {S}_{j} ) \qquad ( 10 )$$

In Eq. (10), K is the tensor of rock permeability defined by Eq. (10A), ∇ is the divergence operator defined by (10B), \vec{l}, \vec{J}, \vec{k} are the unit vectors in x, y and z directions, δ(x, y, x, t) is the Dirac's delta function defined in (x, y, z) space which has integral of 1 and is zero anywhere in the domain except for the location (x, y, x) for a given time t, and the subscript j refers to fluid phase of oil or water.

$$\begin{matrix}K = [ \begin{matrix}{k}_{xx} & {k}_{xy} & {k}_{xz} \\ {k}_{yx} & {k}_{yy} & {k}_{yz} \\ {k}_{zx} & {k}_{zy} & {k}_{zz}\end{matrix} ] & ( 10 A ) \\ ∇ = \frac{\partial }{\partial x} \vec{i} + \frac{\partial }{\partial y} \overline{j} + \frac{\partial }{\partial z} \vec{k} & ( 10 B )\end{matrix}$$

When discretized in space and time, Eq. (1) and Eq. (2) are converted to Eq. (11) and Eq. (12) below.

$$\begin{matrix}{( {\sum }_{k = 1}^{{n}_{f} ( k )} {T}_{r , k , {k}_{n} ( k )} {λ}_{j} {ρ}_{j} ( {Φ}_{j {,}_{{k}_{n} ( k )}} - {Φ}_{j {,}_{k}} ) - {δ}_{k} {ρ}_{j} {q}_{j , k} \}}^{n + 1} = \frac{{( {V}_{p} {ρ}_{j} {S}_{j} )}_{k}^{n + 1} - {( {V}_{p} {ρ}_{j} {S}_{j} )}_{k}^{n}}{Δ t} & ( 11 ) \\ j = oil , water & ( 11 A ) \\ k = 1 , . . Nx * Ny * Nz & ( 11 B ) \\ n = 0 , 1 , 2 , … … NTS & ( 11 C ) \\ {T}_{r , k , {k}_{n} ( k )} = {k}_{k , {k}_{n} ( k )} \frac{{A}_{k , {k}_{n} ( k )}}{{d}_{k , {k}_{n} ( k )}} & ( 12 )\end{matrix}$$

In Eq. (11), j, k and n are defined by Eq. (11A) through Eq. (11C). As defined in Eq. (11A), j represents the fluid phase and fluid component since the oil phase and water phases are considered in this disclosure as being immiscible. As defined in Eq. (11B), k represents the grid block number, Nx is the number of discretization (i.e., grid blocks) in x direction, Ny is the number of grid blocks in y direction, and Nz is the number of grid blocks in z directions. As defined in Eq. (11C), n represents the old time step and NTS is the total number of time steps required to complete the simulation for the time interval (0, T) where T is the final simulation time. In this context, n+1 represents the next time stamp subsequent to the time stamp n within the simulation time interval (0, T).

In Eq. (12), k_{k,k}_{ₙ}₍ₖ₎ is the rock permeability between the grid block k and kₙ(k), which is a neighbor grid block of k, A_{k,k}_{ₙ}₍ₖ₎ is the cross sectional area normal (i.e., perpendicular) to the flow between the neighboring grid blocks k and kₙ(k), and d_{k,k}_{ₙ}₍ₖ₎ is the distance between the centers of the grid blocks k and kₙ(k).

Further in Eq. (11), n_{f}(k) is the number of faces of the grid block k. For example, n_{f}(k)=2 (i.e., East and West faces) for a one dimensional grid, and n_{f}(k)=6 for a three dimensional grid. In addition, λⱼ is the fluid mobility which is defined as

$${λ}_{j} = \frac{{k}_{r , j}}{{μ}_{j}}$$

for the fluid phase j, ρⱼ is the density of fluid j, Φⱼ is the fluid potential for phase j and defined by Eq. (4) and Eq. (5), δₖ is the Dirac's delta function that identifies the grid block k as including a fluid source (e.g., a well), q_{j,k} is the well injection or production rate for phase j, and V_{p,k} is the pore volume of the grid block k, V_{p,k}=(ΔxΔyΔz∅)ₖ.

Based on the initial condition prescribed, and given well rates, the reservoir simulator generates a numerical solution of Eq. (11) and Eq. (12) to predict the amount of water, oil, and phase pressures at a given location and time in the reservoir. Because Eq. (1) through Eq. (12) above describe conservation of oil and water mass, the numerical solution can be generated with a precision acceptable by the engineering standards such as pressure error within 0.5 psi and fluid saturation error less than 0.5 percent. However, as described above, numerical dispersion is known as an artifact of the grid block size and time step size selected for the numerical solution. For larger grid block sizes and time step sizes, the numerical dispersion results in stretching the moving fluid fronts. For example, the numerical solution of the reservoir simulation may show premature breakthrough of the injected fluids at producing wells than what is actually observed in the field. As a result, the placement planning of fluid separation plants (e.g., for gas or water) in the field is adversely effected.

In a conventional method based on the typical water relative permeability, water starts flowing from the grid block k to the next grid block k+1 when the water saturation S_{w,k}≥S_{wc} under a non-zero pressure gradients applied to the grid blocks. To reduce the adverse effect of the numerical dispersion, as described in reference to FIGS. 4.1-4.5 below, the hybrid method determines the aforementioned average water saturation CWS (i.e., S_{w,crit}) at which water starts flowing into the neighboring grid block at the downstream direction.

FIG. 4.1 shows an example water distribution in a one dimensional reservoir grid block at a time step t. In particular, the horizontal x-axis represents a location within the one dimensional grid block that has the length Δx, the vertical axis represents the water saturation S_{w} within the grid block. For a particular grid block k in the reservoir, the water saturation S_{w} depicted in FIG. 4.1 is denoted as S_{W,k}. The water saturation distribution includes region-1 (411), region-2 (412), and region-3 (413) that are three consecutive portions of the grid block length Δx. The region-1 (411) corresponds to the condition that the rock is completely swept by water where S_{w}=1−S_{orw} (the subscript “orw” denotes residual oil saturation). The region-2 (412) corresponds to the condition that the rock is partially swept by water where S_{w} decreases from 1-S_{orw} to S_{wf} (the subscript “wf” denotes water saturation at the front) at the water front (414). The region-3 (413) corresponds to the condition that the rock is in front of the water front where S_{w}=S_{wc} (i.e., connate water saturation). The water distribution profile is the combined water distribution throughout the three regions (411, 412, 413) from the rock being completely swept by water to where the rock is in front of the water front. The average water saturation S̅_̅{̅w̅}̅ (415) is the numerical average of the water saturation S_{w} throughout the region-1 (411), region-2 (412), and region-3 (413). As time progress, S̅_̅{̅w̅}̅ (415) increases as water flows from left to right within the grid block such that the boundary between the region-2 (412) and region-3 (413) moves toward the grid block boundary at the right side of the grid block.

FIG. 4.2 shows the water distribution in the reservoir grid block depicted in FIG. 4.1 but at a subsequent time step t+Δt when the water (414) front reaches the grid block boundary. In other words, the region-3 (413) is pushed out from the grid block and only region-1 (411) and region-2 (412) remains in the grid block. In FIG. 4.2, the average water saturation S̅_̅{̅w̅}̅ (415) is the numerical average of the water saturation S_{w} throughout the region-1 (411) and region-2 (412). As time progress, S̅_̅{̅w̅}̅ (415) increase as the water distribution changes from FIG. 4.1 to FIG. 4.2. When S̅_̅{̅w̅}̅ (415) reaches the critical water saturation S_{w,crit} (also denoted as CWS), the water front reaches the downstream grid block boundary.

FIG. 4.3 illustrates determining the average water saturation S̅_̅{̅w̅}̅ and water saturation at the front S_{wf} using the Welge's method. Specifically, FIG. 4.3 shows the fractional flow curve (431) representing the function ƒ_{w}(S_{w}) of water cut (denoted as f_{w} along the vertical axis) versus water saturation (denoted as S_{w} along the horizontal axis). In particular, ƒ_{w}(S_{w}) is calculated from the reservoir simulator input data as below.

$${f}_{w} ( {S}_{w} ) = \frac{{k}_{rs} ( {S}_{w} )}{{μ}_{w}} \text{/} ( \frac{{k}_{rw} ( {S}_{w} )}{{μ}_{w}} + \frac{{k}_{ro} ( {S}_{w} )}{{μ}_{o}} )$$

In this equation, k_{rw}(S_{w}), kᵣₒ(S_{w}), μ_{w}, and μₒ denote relative permeability of water, relative permeability of oil, viscosity of water, and viscosity mobility of oil, respectively, and are input data for the simulator as a table or an equation.

In the Welge' s method, a tangent (432) to the fractional flow curve (431) is drawn from the connate water saturation (S_{wc}) (433) to locate the tangential point (434). The x-coordinate of the tangential point (434) is determined as the water saturation at the front S_{wf} (435). Eq. (13) below is the Welge equation which relates the average water saturation behind the front S̅_̅{̅w̅}̅ to the water saturation at the front S_{wf} at the water breakthrough from grid block k to grid block k+1.

$$\overline{{S}_{w}} = {S}_{wf} + \frac{1 - {f}_{wf}}{{( \frac{\partial {f}_{w}}{\partial {S}_{w}} )}_{Swf}} \qquad ( 13 )$$

In the hybrid method, the Welge equation is interpreted such as S̅_̅{̅w̅}̅ in Eq. (13) corresponds to the grid block water saturation S̅_̅{̅w̅}̅ depicted in FIG. 4.2 when the water front (with water saturation S_{wf}) reaches the right face (i.e., downstream boundary) of the grid block at a distance of Δx from the left face (i.e., upstream boundary) of the grid block. Based on Eq. (13) where

$${( \frac{\partial {f}_{w}}{\partial {S}_{w}} )}_{Swf}$$

is the slope of the fractional flow curve (431) at the tangent point (434) where the water saturation equals to S_{wf} (434), S̅_̅{̅w̅}̅ is determined as the x-coordinate (i.e., water saturation) of the intersection point (436) where the tangent (432) intersects the horizontal line (437) x-coordinate represented by ƒ_{w}=1.

In reservoir simulation, the average water saturation S̅_̅{̅w̅}̅ computed for the grid block k is denoted as S̅_̅{̅w̅,̅k̅}̅ . As described above for the hybrid method, water starts to flow into the grid block (k+1) from the grid block k when the simulator computed grid block saturation exceeds the critical water saturation S_{w,crit} (also denoted as CWS), i.e., when S̅_̅{̅w̅,̅k̅}̅ exceeds S_{w,crit}.

In the scenario shown in FIGS. 4.1-4.2, the grid block size Δx is large enough to contain all three regions (411, 412, 413). In this scenario, S_{w,crit}=S̅_̅{̅w̅}̅ where S̅_̅{̅w̅}̅ is the average water saturation behind the water front determined using the Welge equation, i.e., determined from the tangent (432) drawn to the fractional flow curve (431) depicted in FIG. 4.3.

In practice, the first scenario depicted in FIG. 4.1-4.2 where the entire partially swept rock region-2 is contained in a single grid block results in numerical dispersion introduced by the reservoir simulator. For example, predicted water breakthrough may be delayed. FIG. 4.4 shows the second scenario where the example water saturation profile is contained in two adjacent grid blocks, i.e., grid block (k−1) and grid block k of a one dimensional reservoir grid. FIG. 4.5 shows the third scenario where the example water saturation profile is contained in three consecutive grid blocks, i.e., grid block (k−2), grid block (k−1), and grid block k of a one dimensional reservoir grid. As compared to the first scenario depicted in FIGS. 4.1-4.2, the smaller grid block size is used in the second and third scenarios results in less numerical dispersion introduced by the simulator.

In FIGS. 4.4-4.5, the water saturation distribution in the partially swept rock region-2 can be estimated by the following empirical saturation equation Eq. (14).

$${S}_{w} ( x ) = \frac{1 - {S}_{orw}}{1 + b \overline{x} + c {\overline{x}}^{2}} \qquad ( 14 )$$

In Eq. (14), x̅ is the normalized horizontal distance from the left corner of the grid block containing the boundary between the region-1 and region-2,

$$\overline{x} = \frac{x}{Δ x} ,$$

0≤x̅≥1.

Eq. (14) has two unknown parameters to be determined, namely b and c. Eq. (14) satisfies the left boundary condition where at

x̅=0, S_{w}(0)=1−S_{orw}

The unknown parameters b and c can be determined from the following two equations Eq. (15) and Eq. (16).

$$\begin{matrix}\frac{1 - {S}_{orw}}{1 + b \overline{x} + c {\overline{x}}^{2}} = {S}_{wf} & ( 15 ) \\ {\int }_{0}^{1} \frac{1 - {S}_{orw}}{1 + b \overline{x} + c {\overline{x}}^{2}} d \overline{x} = \overline{{S}_{w}} & ( 16 )\end{matrix}$$

In Eq. (15) and Eq. (16), S_{wf} is the water saturation at the front and S̅_̅{̅w̅}̅ is the average water saturation behind the front. Both can be determined by drawing a tangent of the ƒ_{w}(S_{w}) curve. The fractional flow curve ƒ_{w} (S_{W}) is computed by the mobility (i.e., viscosity) ratio in Eq. (17) below with no gravity and capillary effects.

$${f}_{w} = \frac{1}{1 + \frac{{k}_{ro}}{{k}_{rw}} \frac{{μ}_{w}}{{μ}_{o}}} \qquad ( 17 )$$

In Eq. (17), kᵣₒ denotes relative permeability of oil, k_{rw} denotes relative permeability of water, μ_{w} denotes viscosity of water, and μₒ denotes viscosity of oil.

The hybrid method solves the expression for the parameter c from Eq. (15) and substituting the expression in Eq. (16) to obtain a nonlinear equation for the unknown parameter b. The new equation involves integration. Integration in the expression is evaluated numerically during the iterations for the unknown parameter b. Parameter b can be solved by nonlinear iterations. After determining the parameters b and c, the water saturation distribution within the grid block is described by Eq. (14).

In FIG. 4.4, the average water saturation (441) of the grid block k at breakthrough (i.e., water front reaching the right side of the grid block k) is denoted as S̅_̅{̅w̅,̅k̅}̅ and is calculated from the Eq. (18) using the parameters b and c determined above.

$$\overline{{S}_{w , k}} = \frac{1}{2} {\int }_{\frac{1}{2}}^{1} \frac{1 - {S}_{orw}}{1 + b \overline{x} + c {\overline{x}}^{2}} d \overline{x} \qquad ( 18 )$$

In FIG. 4.5, the average water saturation (451) of the grid block k at breakthrough (i.e., water front reaching the right side of the grid block k) is denoted as S̅_̅{̅w̅,̅k̅}̅ and is calculated from the Eq. (19) using the parameters b and c determined above.

$$\overline{{S}_{w , k}} = \frac{1}{3} {\int }_{\frac{2}{3}}^{1} \frac{1 - {S}_{orw}}{1 + b \overline{x} + c {\overline{x}}^{2}} d \overline{x} \qquad ( 19 )$$

The hybrid method uses the S̅_̅{̅w̅,̅k̅}̅ computed from Eq. (18) and Eq. (19) as the S_{w,crit} for the reservoir simulator. In addition to computing the S̅_̅{̅w̅,̅k̅}̅ for providing to the reservoir simulator, the hybrid method adjusts the water and oil relative permeability curves to further improve the simulation results for matching the water breakthrough between adjacent grid blocks.

FIG. 4.7 shows an example water relative permeability curve (k_{rw}) (471) where the horizontal axis corresponds to water saturation S_{w} and the vertical axis corresponds to relative permeability Kᵣ. The hybrid method generates a modified water relative permeability (k_{rw,pseudo}) curve by adding a front tail curve (472) to the water relative permeability curve (K_{rw}) (471). The modified water relative permeability (k_{rw,pseudo}) curve starts from S_{w,crit} (473) and connect to the original water relative permeability (k_{rw}) curve (471) at S̅_̅{̅w̅}̅ (474). The modified water relative permeability (k_{rw,pseudo}) curve coincides with the original water relative permeability (k_{rw}) curve (471) from S_{w}=S̅_̅{̅w̅}̅ to S_{w}=1. To avoid a steep section of the modified water relative permeability (k_{rw,pseudo}) curve when S_{w,crit} is numerically close to S_{w}, a user selected adjustment parameter ΔS_{w,tail} may be selected to widen the difference. After such adjustment, S_{w,crit=}S̅_̅{̅w̅}̅−ΔS_{w,tail}·ΔS_{w,tail} is usually a small number, e.g., between 0.01 and 0.05.

FIG. 4.8 shows an example water relative permeability curve (k_{rw}) (471) and oil relative permeability curve (k_{row}) (481), which correspond to Eq. (20) and Eq. (21), respectively. The hybrid method generates a modified water relative permeability (k_{rw,pseudo}) curve by adding a front tail curve (472) to the water relative permeability curve (K_{rw}) (471). Similarly, the hybrid method generates a modified oil relative permeability (k_{row,pseudo}) curve (482) to the oil relative permeability (K_{rw}) curve (481).

$$\begin{matrix}{k}_{rw} = {( \frac{{S}_{w} - {S}_{wc}}{1 - {S}_{wc} - Sorw} )}^{{n}_{w}} & ( 20 ) \\ {k}_{row} = {( \frac{{S}_{o} - Sorw}{1 - {S}_{wc} - Sorw} )}^{{n}_{o}} & ( 21 )\end{matrix}$$

After selecting the new critical water saturation S_{w,crit} (473) based on the selected tail water saturation ΔS_{w,tail}, the modified water relative permeability (k_{rw,pseudo}) curve (472) corresponds to Eq. (22) and Eq. (23) below.

$$\begin{matrix}For {S}_{w , crit} \leq {S}_{w} \leq \overline{{S}_{w}} \text{:} {k}_{rw , pseudo} = {( \frac{{S}_{w} - {S}_{w , critical}}{1 - {S}_{w , critical} - Sorw} )}^{{n}_{wp}} & ( 22 ) \\ For {S}_{w} \geq \overline{{S}_{w}} \text{:} {k}_{rw} = {( \frac{{S}_{w} - {S}_{wc}}{1 - {S}_{wc} - Sorw} )}^{{n}_{w}} & ( 23 )\end{matrix}$$

Where the new exponent n_{wp} is selected such that the front tail curve (472) is connected to the original water relative permeability curve (k_{rw}) (471) as a continuous curve with smooth derivatives.

Changing water and oil relative permeability curves as described above may change the computed pressure fields (e.g., pₒ in Eq. (4) above) by the simulator, i.e., in Eq. (1)-Eq. (9). To correct computed pressure fields, the hybrid method further adjusts the water and oil relative permeability curves such that the total flux between the two adjacent grid blocks remains constant. Maintaining constant total flux is justified for constant fluid densities, and is a good approximation for oil water flow above the bubble point pressures.

Assuming that total mobility of the modified system is equal to the total mobility of the original water oil relative permeability system and using the rock relative permeability, total fluid mobility at a given water saturation at any point in the reservoir is preserved by the new pseudo relative permeability curves. In other words, Eq. (24) holds for obtaining the same pressure solution for any water and oil saturations.

$$\frac{{k}_{rw}}{{μ}_{w}} + \frac{{k}_{row}}{{μ}_{o}} = \frac{{k}_{rw , pseudo}}{{μ}_{w}} + \frac{{k}_{row , pseudo}}{{μ}_{o}} \qquad ( 24 )$$

Since the modified water relative permeability curve is redefined as the k_{rw,pseudo} curve using S̅_̅{̅w̅}̅ and S_{wf} from the Welge Equation (i.e., Eq. (13)), the modified oil relative permeability (k_{row,pseudo}) curve is derived as Eq. (25) from the Eq. (24) where

$$δ {k}_{rw} = \frac{{μ}_{o}}{{μ}_{w}} ( {k}_{rw} - {k}_{rw , pseudo} ) .$$

$${k}_{row , pseudo} = {k}_{row} + \frac{{μ}_{o}}{{μ}_{w}} δ {k}_{rw} \qquad ( 25 )$$

In Eq. (25), the modified oil relative permeability (k_{rw,pseudo}) equals to the original oild relative mobility (k_{rw}) plus a correction term caused by the front tail curve (472) added to the water relative permeability curve (K_{rw}) (471) such that the pressure field computed by the original water and oild relative permeability curves are preserved.

TABLE 1 shows reservoir and fluid data for an example one dimensional (1D) reservoir model of a reservoir having an area of 2400 ft×2400 ft with a thickness of 40 ft. The reservoir is represented as a 1D grid depicted in FIG. 4.9 where each grid block having a width of 600 ft and a thickness of 15 ft. The water injector well (491) and the producer well (492) are placed in the opposite corners of the 1D grid. Four example grid sizes along the length direction are used to generate four set of simulation results as shown in TABLE 2 below. For each simulation run, the reservoir model is assumed to have uniform permeability and porosity. Initially, the reservoir is saturated with oil above the bubble point pressure and contains initial water saturation at S_{wc}, with irreducible oil saturation of S_{orw} uniformly across the reservoir.

TABLE 1
Reservoir and fluid data

| Areal Model Size | 2400 ft × 2400 ft | |
|---|---|---|
| Reservoir Thickness | 40 | ft. |
| Initial Pressure | 2500 | psi |
| Initial Oil Saturation | 0.80 | |
| Initial Water Saturation | 0.20 | |
| Maximum oil-water Capillary Pressures | 180 | psi |
| Pressure at oil water contact & 8010 ft | 3200 | psi |
| Permeability in x & y | 500 | md |
| Vertical Permeability in z | 1 | md |
| Porosity | 0.20 | |
| Oil, water and rock compressibility, | 3.E−6 1/psi | |
| Standard Oil Density, | 50 | Lbs./SCF |
| Standard Water Density | 62.4 | lbs./SCF |
| Oil Viscosity | 1.5 | Cp |
| Water Viscosity | 0.5 | Cp |
| Oil Relative Permeability Exponent | 2 | |
| Water Relative Permeability Exponent | 2 | |
| S_{orw} | 0.20 | |
| S_{wc} | 0.20 | |
| Newton Tolerance for pressure | 0.5 | psi |
| Newton Tolerance for Saturation | 0.005 | |
| Water Injection Rate - 2D and 3D Models | 5,000 | STB/Day |
| Total Liquid Production Rate at the | 5,000 | STB/Day |
| producing well - 2D and 3D Models | | |
| 1D Model Injection and production rate | 1,250 | STB/D |

Using the fluid data and relative permeability curves shown in FIG. 4.6, the fractional flow curve is generated as shown in FIG. 4.3. The Welge method is then applied to the fractional flow curve to obtain S_{wf}=0.50, and S̅_̅{̅w̅}̅=0.6.

TABLE 2 shows four sets of example simulation results using different 1D grid sizes. The simulation result of the third case corresponds to a fine grid simulation where the grid block size is set to 24 ft along the length direction in FIG. 4.9. The fine grid simulation in the third case predicts the correct water breakthrough time 0.35 with negligible numerical dispersion.

TABLE 2
One dimensional Model Results

| | | | | | Water Breakthrough | Percent |
|---|---|---|---|---|---|---|
| | Nx = | | | | Time at Producer, | Error, |
| | Number | | Injection | Production | Dimensionless | In Water |
| | of Grid | Grid Block | Rate | Rate | Cumulative Pore | Breakthrough |
| Case | Blocks | Size, ft. | STB/Day | STB/Day | Volume Injected | (BT) time |
| 1 | 4 | 600 | 1,250 | 1,250 | 0.23 | 34% |
| 2 | 60 | 100 | 1,250 | 1,250 | 0.31 | 11% |
| 3 | 100 | 24 | 1,250 | 1,250 | 0.35* | 0% |
| 4 | 4 Hybrid | 600 | 1,250 | 1,250 | 0.37 | 6% |
| | Method | | | | | |

*correct water breakthrough time with negligible numerical dispersion

FIG. 4.12 shows case 1, case 3, and case 4 of the four simulation results listed in TABLE 2 above that are plotted in terms of producing water cut at the production well versus dimensionless pore volume (PV) injected. The dimensionless PV injected corresponds to the ratio of injected water volume over total pore volume. FIG. 4.12 also shows case 5 that is not explicitly listed in TABLE 2.

As shown in TABLE 2 and FIG. 4.12, the coarse grid simulation result of the first case with 4 grid blocks in the 1D grid predicts a premature water breakthrough time 0.23 which has a 34% error compared to the correct water breakthrough time 0.35 predicted by the fine grid simulation result of the third case. The fourth case corresponds to the hybrid method applied to the coarse grid simulation of the first case with 4 grid blocks in the 1D grid. The simulation result of the hybrid method in the fourth case predicts a close match in the water breakthrough time 0.37 which has a mere 6% error compared to the correct water breakthrough time 0.35 predicted by the fine grid simulation result of the third case. The hybrid method coarse grid simulation of the fourth case has the advantage of 25 times faster (i.e., shorter) simulation time compared to the fine grid simulation of the third case.

FIGS. 4.13 and 4.14 show two simulation results listed in TABLE 2 above that are plotted in terms of oil pressure and water saturation, respectively, versus normalized position xd along the length direction of the 1D grid shown in FIG. 4.9. The normalized position xd is calculated as x/L where L=2400 ft, which is the length of the reservoir. Specifically, FIGS. 4.13 and 4.14 correspond to the fine grid simulation result of the third case and the hybrid method coarse grid simulation result of the forth case listed in TABLE 2. As shown in FIGS. 4.13 and 4.14, the hybrid method coarse grid simulation result matches well with the fine grid simulation result in the oil pressure profile and the water saturation profile. As noted above, the hybrid method coarse grid simulation of the fourth case has the advantage of 25 times faster (i.e., shorter) simulation time compared to the fine grid simulation of the third case.

FIG. 4.10 shows an example two-dimensional (2D) grid representing the reservoir in the numerical simulation where water injector well (491) and the producer well (492) are placed in the opposite corners of the 2D grid. TABLE 3 shows four sets of example simulation results using different 2D grid sizes. The simulation result of the third case corresponds to a fine grid simulation where the grid block size is set to 24 ft on each side. The fine grid simulation in the third case predicts the correct water breakthrough time 0.36 with negligible numerical dispersion.

TABLE 3
Two dimensional Model Results

| | | | | | Water Breakthrough | |
|---|---|---|---|---|---|---|
| | Nx Ny = | | | | Time at Producer, | Percent |
| | Number | | Injection | Production | Dimensionless | Error, |
| | of Grid | Grid Block | Rate | Rate | Cumulative Pore | In BT |
| Case | Blocks | Size, ft. | STB/Day | STB/Day | Volume Injected | time |
| 1 | 4 × 4 | 600 | 5,000 | 5,000 | 0.23 | 36% |
| 2 | 60 × 60 | 60 | 5,000 | 5,000 | 0.31 | 14% |
| 3 | 100 × 100 | 24 | 5,000 | 5,000 | 0.36* | 0.0% |
| 4 | 4 × 4, | 600 | 5,000 | 5,000 | 0.38 | 5% |
| | Hybrid | | | | | |
| | Method | | | | | |

*correct water breakthrough time with negligible numerical dispersion

FIG. 4.15 shows four simulation results listed in TABLE 3 above that are plotted in terms of producing water cut at the production well versus dimensionless pore volume injected. As shown in FIG. 4.15, the hybrid method coarse grid simulation result matches well with the fine grid simulation result in the water breakthrough time.

As shown in TABLE 3 and FIG. 4.15, the coarse grid simulation result of the first case with 4×4 grid blocks in the 2D grid predicts a premature water breakthrough time 0.23 which has a 36% error compared to the correct water breakthrough time 0.36 predicted by the fine grid simulation result of the third case. The fourth case corresponds to the hybrid method applied to the coarse grid simulation of the first case with 4×4 grid blocks in the 2D grid. The simulation result of the hybrid method in the fourth case predicts a close match in the water breakthrough time 0.38 which has a mere 5% error compared to the correct water breakthrough time 0.36 predicted by the fine grid simulation result of the third case.

FIG. 4.11 shows an example three-dimensional (3D) grid representing the reservoir in the numerical simulation where water injector well (491) and the producer well (492) are placed in the opposite corners of the 3D grid. TABLE 4 shows four sets of example simulation results using different 3D grid sizes. The simulation result of the third case corresponds to a fine grid simulation where the grid block size is set to 24 ft by 24 ft by 2 ft. The fine grid simulation in the third case predicts the correct water breakthrough time 0.40 with negligible numerical dispersion.

TABLE 4
Three Dimensional Model Results

| | | | | | Water Breakthrough | |
|---|---|---|---|---|---|---|
| | | | | | Time at Producer, | Percent |
| | Number | | Injection | Production | Dimensionless | Error, |
| | of Grid | Grid Block | Rate | Rate | Cumulative Pore | In BT |
| Case | Blocks | Size, ft. | STB/Day | STB/Day | Volume Injected | time |
| 1 | 4 × 4 × 2 | 600 × 600 × 20 | 5,000 | 5,000 | 0.21 | 48% |
| 2 | 60 × 60 | 60 × 60 × 20 | 5,000 | 5,000 | 0.314 | 22% |
| 3 | 100 × 100 | 24 × 24 × 20 | 5,000 | 5,000 | 0.40* | 0.0% |
| 4 | 4 × 4 × 2 | 600 × 600 × 20 | 5,000 | 5,000 | 0.38 | 5% |
| | Hybrid | | | | | |
| | Method | | | | | |

*correct water breakthrough time with negligible numerical dispersion

FIG. 4.16 shows four simulation results listed in TABLE 4 above that are plotted in terms of producing water cut at the production well versus dimensionless time which is taken as dimensionless pore volume water injected. As shown in FIG. 4.16, the hybrid method coarse grid simulation result matches well with the fine grid simulation result in the water breakthrough time.

As shown in TABLE 4 and FIG. 4.16, the coarse grid simulation result of the first case with 4×4×2 grid blocks in the 3D grid predicts a premature water breakthrough time 0.21 which has a 48% error compared to the correct water breakthrough time 0.40 predicted by the fine grid simulation result of the third case. The fourth case corresponds to the hybrid method applied to the coarse grid simulation of the first case with 4×4×2 grid blocks in the 3D grid. The simulation result of the hybrid method in the fourth case predicts a close match in the water breakthrough time 0.38 which has a mere 5% error compared to the correct water breakthrough time 0.40 predicted by the fine grid simulation result of the third case. As shown in TABLE 5 below, the hybrid method coarse grid simulation of the fourth case has the advantage of over 1000 times faster (i.e., shorter) simulation time compared to the fine grid simulation of the third case.

As the number of grid blocks used in a numerical simulation increases, total simulation time used by the computer processor increases proportionally. As the size of grid blocks used in a numerical simulation decreases, total simulation time used by the computer processor also increases proportionally. Therefore, use of coarse grids in the simulation provides faster simulation (i.e., shorter simulation time) to allow testing many production and injection scenarios in a given computer run time period.

TABLE 5 summarizes the computation speed gain by using the hybrid method.

TABLE 5
Run Time Comparison

| Number of Grid Blocks | How many times faster |
|---|---|
| 100 × 100 × 1 | 1 |
| 4 × 4 × 1 - Hybrid Method | 1,700 |
| 100 × 100 × 2 | 1 |
| 4 × 4 × 1- Hybrid Method | 4,000 |

TABLE 6 shows three sets of example simulation results with reservoir heterogeneity included in the 3D model. Instead of assuming constant permeability and porosity throughout the reservoir, the 3D model includes permeability and porosity field by adding a normally distributed random noise to the reservoir data. Vertical permeability is assumed to be 1 percent of the horizontal permeability. In addition, heterogeneity in Kₓ and K_{y} is assumed to be 500 md with standard deviation equal to 50 md. The porosity is assumed to be a normal distribution with mean equal to 0.20 and standard deviation equal to 0.02 based on arithmetic average.

TABLE 6
Two Dimensional Heterogeneous Reservoir Results

| | | | | | Water Breakthrough | |
|---|---|---|---|---|---|---|
| | | | | | Time at Producer, | Percent |
| | Number | | Injection | Production | Dimensionless | Error, |
| | of Grid | Grid Block | Rate | Rate | Cumulative Pore | In BT |
| Case | Blocks | Size, ft. | STB/Day | STB/Day | Volume Injected | time |
| 1 | 4 × 4 × 1 | 600 | 5,000 | 5,000 | 0.21 | 42% |
| 3 | 100 × 100 × 1 | 24 | 5,000 | 5,000 | 0.36* | 0% |
| 4 | 4 × 4 × 1, | 600 | 5,000 | 5,000 | 0.35 | 3% |
| | Hybrid | | | | | |
| | Method | | | | | |

*correct water breakthrough time with negligible numerical dispersion

As shown in TABLE 6, the reservoir heterogeneity described above does not change the simulation result significant. Similar to a homogeneous reservoir model, the hybrid method yields water breakthrough time within 5 percent of the fine grid simulation model.

Embodiments may be implemented on a computing system. Any combination of mobile, desktop, server, router, switch, embedded device, or other types of hardware may be used. For example, as shown in FIG. 5A, the computing system (500) may include one or more computer processors (502), non-persistent storage (504) (e.g., volatile memory, such as random access memory (RAM), cache memory), persistent storage (506) (e.g., a hard disk, an optical drive such as a compact disk (CD) drive or digital versatile disk (DVD) drive, a flash memory, etc.), a communication interface (512) (e.g., Bluetooth interface, infrared interface, network interface, optical interface, etc.), and numerous other elements and functionalities.

The computer processor(s) (502) may be an integrated circuit for processing instructions. For example, the computer processor(s) may be one or more cores or micro-cores of a processor. The computing system (500) may also include one or more input devices (510), such as a touchscreen, keyboard, mouse, microphone, touchpad, electronic pen, or any other type of input device.

The communication interface (512) may include an integrated circuit for connecting the computing system (500) to a network (not shown) (e.g., a local area network (LAN), a wide area network (WAN) such as the Internet, mobile network, or any other type of network) and/or to another device, such as another computing device.

Further, the computing system (500) may include one or more output devices (508), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (502), non-persistent storage (504), and persistent storage (506). Many different types of computing systems exist, and the aforementioned input and output device(s) may take other forms.

Software instructions in the form of computer readable program code to perform embodiments of the disclosure may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments of the disclosure.

The computing system (500) in FIG. 5A may be connected to or be a part of a network. For example, as shown in FIG. 5B, the network (520) may include multiple nodes (e.g., node X (522), node Y (524)). Each node may correspond to a computing system, such as the computing system shown in FIG. 5A, or a group of nodes combined may correspond to the computing system shown in FIG. 5A. By way of an example, embodiments of the disclosure may be implemented on a node of a distributed system that is connected to other nodes. By way of another example, embodiments of the disclosure may be implemented on a distributed computing system having multiple nodes, where each portion of the disclosure may be located on a different node within the distributed computing system. Further, one or more elements of the aforementioned computing system (500) may be located at a remote location and connected to the other elements over a network.

Although not shown in FIG. 5B, the node may correspond to a blade in a server chassis that is connected to other nodes via a backplane. By way of another example, the node may correspond to a server in a data center. By way of another example, the node may correspond to a computer processor or micro-core of a computer processor with shared memory and/or resources.

While the disclosure has been described with respect to a limited number of embodiments, those skilled in the art, having benefit of this disclosure, will appreciate that other embodiments can be devised which do not depart from the scope of the disclosure as disclosed herein. Accordingly, the scope of the disclosure should be limited only by the attached claims.

Although the preceding description has been described herein with reference to particular means, materials and embodiments, it is not intended to be limited to the particulars disclosed herein; rather, it extends to all functionally equivalent structures, methods and uses, such as are within the scope of the appended claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed is:

1. A method for reservoir simulation, comprising:
selecting a coarse grid size for a plurality of grid blocks in a reservoir model of a reservoir;
computing, by a computer processor and based at least on a fractional flow curve of oil and water, a water saturation at a water front within a grid block of the plurality of grid blocks and an average water saturation of the grid block; and
computing, by the computer processor and based at least on the water saturation at the water front within the grid block and the average water saturation of the grid block, a water saturation distribution in the reservoir by solving reservoir simulator equations,
wherein solving the reservoir simulator equations comprises computing a single water saturation value for each of the plurality of grid blocks based on the coarse grid size.

2. The method of claim 1,
wherein computing the water saturation at the water front within the grid block and the average water saturation of the grid block comprises solving a Welge equation of the fractional flow curve based on a local boundary condition.

3. The method of claim 1, further comprising:
determining an empirical saturation equation, comprising at least one empirical parameter, that describes the water saturation distribution in a partially water swept rock region behind the water front in the grid block;
determine the at least one empirical parameter by applying the water saturation at the water front within the grid block and the average water saturation of the grid block to the empirical saturation equation; and
integrating the empirical saturation equation over the grid block based on the water front reaching a downstream boundary of the grid block to compute a critical water saturation;
wherein solving the reservoir simulator equations comprises determining water starting flowing into a neighboring downstream grid block when a simulator computed water saturation reaches the critical water saturation.

4. The method of claim 3, further comprising:
determining, based on the critical saturation, a saturation range; and
modifying, within the saturation range, oil and water relative permeability curves of the reservoir model,
wherein solving the reservoir simulator equations is based on the modified oil and water relative permeability curves.

5. The method of claim 4,
wherein modifying the oil and water relative permeability curves comprises adding a front tail to the oil and water relative permeability curves within the saturation range, and
wherein modifying the oil and water relative permeability curves preserves a pressure solution with respect to a fine grid reservoir simulation solution.

6. The method of claim 1, further comprising:
simulating water movement across the reservoir based on computing the water saturation distribution for each of a plurality of time steps of the reservoir simulation.

7. The method of claim 1, further comprising:
performing, based at least on the water saturation distribution in the reservoir, a field operation.

8. The method of claim 2,
wherein the Welge equation is represented by
$$\overline{{S}_{w}} = {S}_{wf} + \frac{1 - {f}_{wf}}{{( \frac{\partial {f}_{w}}{\partial {S}_{w}} )}_{Swf}} ,$$
where S denotes the average water saturation of the grid block, S_{wf} denotes the water saturation at the water front within the grid block, S_{w} denotes the water saturation as a function of a location in the grid block, ƒ_{w} denotes the fractional flow curve as a function of S_{W} and ƒ_{wf} denotes a value of the functional flow curve at the water font within the grid block.

9. The method of claim 3,
wherein the empirical saturation equation is represented by
$${S}_{w} ( x ) = \frac{1 - {S}_{orw}}{1 + b \overline{x} + c {\overline{x}}^{2}} ,$$
where S_{w} (x) denotes the water saturation as a function of a location in the grid block, S_{orw} denotes a residual oil saturation, b and c denote the empirical parameter, x denotes a distance of the location from an upstream boundary of the grid block, and x̅ denotes a normalized version of x. partially water swept rock region

10. The method of claim 3,
wherein the coarse grid size is selected such that the partially water swept rock region is contained in at two or three consecutive grid blocks of the plurality of grid blocks.

11. A computer system for performing reservoir simulation, comprising:
a processor; and
a memory coupled to the processor and storing instruction, the instructions, when executed by the processor, comprising functionality for:
selecting a coarse grid size for a plurality of grid blocks in a reservoir model of a reservoir;
computing, based at least on a fractional flow curve of oil and water, a water saturation at a water front within a grid block of the plurality of grid blocks and an average water saturation of the grid block; and
computing, based at least on the water saturation at the water front within the grid block and the average water saturation of the grid block, a water saturation distribution in the reservoir by solving reservoir simulator equations,
wherein solving the reservoir simulator equations comprises computing a single water saturation value for each of the plurality of grid blocks based on the coarse grid size.

12. The computer system of claim 11,
wherein computing the water saturation at the water front within the grid block and the average water saturation of the grid block comprises solving a Welge equation of the fractional flow curve based on a local boundary condition.

13. The computer system of claim 11, the instructions, when executed by the processor, further comprising functionality for:
determining an empirical saturation equation, comprising at least one empirical parameter, that describes the water saturation distribution in a partially water swept rock region behind the water front in the grid block;
determine the at least one empirical parameter by applying the water saturation at the water front within the grid block and the average water saturation of the grid block to the empirical saturation equation; and
integrating the empirical saturation equation over the grid block based on the water front reaching a downstream boundary of the grid block to compute a critical water saturation;
wherein solving the reservoir simulator equations comprises determining water starting flowing into a neighboring downstream grid block when a simulator computed water saturation reaches the critical water saturation.

14. The computer system of claim 13, the instructions, when executed by the processor, further comprising functionality for:
determining, based on the critical saturation, a saturation range; and
modifying, within the saturation range, oil and water relative permeability curves of the reservoir model,
wherein solving the reservoir simulator equations is based on the modified oil and water relative permeability curves.

15. The computer system of claim 14,
wherein modifying the oil and water relative permeability curves comprises adding a front tail to the oil and water relative permeability curves within the saturation range, and
wherein modifying the oil and water relative permeability curves preserves a pressure solution with respect to a fine grid reservoir simulation solution.

16. The computer system of claim 11, the instructions, when executed by the processor, further comprising functionality for:
simulating water movement across the reservoir based on computing the water saturation distribution for each of a plurality of time steps of the reservoir simulation.

17. The computer system of claim 11, the instructions, when executed by the processor, further comprising functionality for:
performing, based at least on the water saturation distribution in the reservoir, a field operation.

18. The computer system of claim 12,
wherein the Welge equation is represented by
$$\overline{{S}_{w}} = {S}_{wf} + \frac{1 - {f}_{wf}}{{( \frac{\partial {f}_{w}}{\partial {S}_{w}} )}_{Swf}} ,$$
where S denotes the average water saturation of the grid block, S_{wf} denotes the water saturation at the water front within the grid block, S_{W} denotes the water saturation as a function of a location in the grid block, ƒ_{w} denotes the fractional flow curve as a function of S_{w} and ƒ_{wf} denotes a value of the functional flow curve at the water font within the grid block.

19. The computer system of claim 13,
wherein the empirical saturation equation is represented by
$${S}_{w} ( x ) = \frac{1 - {S}_{orw}}{1 + b \overline{x} + c {\overline{x}}^{2}} ,$$
where S_{w} (x) denotes the water saturation as a function of a location in the grid block, S_{orw} denotes a residual oil saturation, b and c denote the empirical parameter, x denotes a distance of the location from an upstream boundary of the grid block, and x̅ denotes a normalized version of x. partially water swept rock region

20. The computer system of claim 13,
wherein the coarse grid size is selected such that the partially water swept rock region is contained in two or three consecutive grid blocks of the plurality of grid blocks.
